(19) United States
(12) Patent Application Publication
(10) Pub. No.: US 2008/0220547 A1
(43) Pub. Date: Sep. 11, 2008

(54) SINGLE-CHIP SURFACE MOUNTED LED STRUCTURE AND A METHOD FOR MANUFACTURING THE SAME

(76) Inventors: Tsung-Wen CHAN, Taipei City (TW); Chin-Hsiang Ku, Taipei City (TW)

Correspondence Address: SINORICA, LLC, 528 FALLSGROVE DRIVE, ROCKVILLE, MD, 20850, US

(21) Appl. No.: 11/684,008

(22) Filed: Mar. 9, 2007

(51) Int. Cl. H01L 21/00

(52) U.S. Cl. 438/22

(57) ABSTRACT

A single-chip surface mounted LED structure and a method for manufacturing the same, said LED structure mainly comprises an LED chip, a heat sink structure, two opposing electrodes, conducting wires and a supporting structure; said method comprises the steps of firstly cutting off a spare area other than said heat sink structure and two opposing electrodes from a metal material belt, forming a basic shape, forming said supporting structure in the region of said heat sink structure and two opposing electrodes using plastic injection molding, and then further cutting off the rest of said metal material belt to separate said heat sink structure and two opposing electrodes, and finally using chip-bonding and wire bonding to package sad LED structure and cutting off said packaged LED structure from said metal material belt.

### BACKGROUND OF THE INVENTION

1. Field of the Invention

The present invention relates to a single-chip surface mounted LED structure and a method for manufacturing the same, and more particularly, to an LED manufacturing technique which can provide a heat sink structure to surface mounted LEDs to reduce energy loss and to simplify manufacturing and also contributes to environmental conservation.

2. Description of the Prior Art

Among all kinds of optoelectronics components, LED (Light Emitting Diode) have the advantages of small form factor, long lifetime, fast response, energy saving, shock proof, low cost and volume production capability, therefore LED has long been used in a wide range of application and has the greatest market value among various optoelectronics components.

LED is a lighting component built by semiconductor process and has two electrode terminals. The basic operation of LED is that, when applying voltage between two electrodes, a small current would be generated to trigger the combination of electrons and holes inside the LED, the energy released from electrons/holes combination is radiated in the form of light. Also, different from general light bulbs, LED is a cold lighting source, which provides advantages such as low energy consumption, long lifetime, zero warm-up time, and fast response time. Furthermore, LED has small form factor, and it is shock proof and suitable for volume production and for building small or array type components. Therefore, LEDs have been widely adopted in indicators and display devices used in information, communication and consumer electronics, and have become an indispensable component used in daily life.

LED chips are packaged based on different requirements of end products into different kinds of LEDs, which include LEDs of lamp type, cluster type, digit display type, dot matrix type and surface mounted (SMD) type, wherein SMD type provides smaller footprint than other type, therefore it is used in backlight module and keypad of cellular phone with high market demands.

The above-mentioned LED does not have heat dissipation problem since it generates less heat than a general light bulb. However, the emerging high-brightness LED products would generate considerably more heat than the above-mentioned LED, let alone LED array. Therefore, in modern design of LED, heat sink structure has become a necessity in the manufacturing process.

The FIG. 4 of U.S. Pat. No. 7,138,660 disclosed a traditional SMD type LED having its LED chip disposed on the anode and then routing it wires from the LED chip to the anode and the cathode. The packaged SMD type LED doesn't need additional optical components or reflector to keep the light path parallel to respective circuit board. This SMD type LED uses metal disposed on the anode to dissipate heat to the outside.

However, the above mentioned LED structure or other types of LED products often encounter the following heat dissipation problems, which need to be dealt with:

1. The heat dissipating mechanism used in traditional LED can not efficiently handle all the generated heat, which cause the brightness to degrade when LED's temperature goes up, furthermore, when the temperature passes beyond 85° C., the degradation will worsen.

2. The phosphor used in LED packaging tends to absorb moisture if its temperature goes too high, and then the moisture would darken the phosphor and reduce the lighting efficiency and the capability of LED.

3. Traditional LED design uses copper foil on PCB to dissipate heat; however, due to low heat dissipating efficiency of the two electrodes, it is not a viable solution to dissipate all the heat generated by LED.

4. Traditional LED design does not employ heat dissipating mechanism in packaging process, therefore it is likely that a considerable amount of heat dissipation and processing problems could arise and is not efficient from the viewpoint of economy.

In view of the above-described deficiencies of traditional LED products and the method for manufacturing the same, after years of constant effort in research and practical applications, the inventor of this invention has consequently developed and proposed an enhanced single-chip surface mounted LED structure and also its manufacturing method in the present invention to provide both a simple design and low energy consumption design.

### SUMMARY OF THE INVENTION

It is an objective of the present invention to provide a single-chip surface mounted LED structure and a method for manufacturing the same. The present invention uses an added heat sink structure to fully dissipate heat generated by LEDs and to effectively extend product lifetime and lighting efficiency without adding too much cost.

It is another objective of the present invention to provide a single-chip surface mounted LED structure and a method for manufacturing the same, wherein its heat sink structure is able to combine with the heat dissipating mechanism on the PCB to more efficiently dissipate heat generated by LEDs.

The single-chip surface mounted LED structure comprises an LED chip and two opposing electrodes, while two conducting wires are distributed around the LED chip and extend from the LED chip to the two opposing electrodes; the present invention is characterized in that a heat sink structure extends from an end of said LED chip to dissipate the heat from the LED chip to a printed circuit board (PCB), and the heat could be further dissipated via a heat dissipating mechanism such as copper foil on the PCB or the metal backplane of the PCB; furthermore, a support structure is disposed between the heat sink structure and the two opposing electrodes to hold the heat sink structure and the two opposing electrodes in position to facilitate the packaging process of the single-chip surface mounted LED structure.

Based on the above mentioned structure, the method for manufacturing the single-chip surface mounted LED structure comprises the steps of firstly cutting off a spare area other than the heat sink structure and two opposing electrodes from a metal material belt, forming a basic shape, forming the supporting structure in the range of the heat sink structure and two opposing electrodes using plastic injection molding, and then further cutting off the rest of the metal material belt to separate the heat sink structure and the two opposing electrodes, and finally using chip-bonding and wire bonding to package the LED structure and cutting off said packaged LED structure from said metal material belt.

### BRIEF DESCRIPTION OF THE DRAWINGS

The drawings disclose an illustrative embodiment of the present invention which serves to exemplify the various advantages and objects hereof, and are as follows:

FIG. 1 illustrates a single-chip surface mounted LED structure disclosed in the present invention;

FIG. 2 illustrates a side view of the single-chip surface mounted LED structure disclosed in the present invention;

FIG. 4 illustrates the structure for cutting off a spare metal material belt area in the first step;

FIG. 5 illustrates the placement of support structure in the second step;

FIG. 6 illustrates the cut metal material belt structure after the third step; and

FIG. 7 illustrates the wire bonding and chip bonding structures in the fourth step.

### REFERENCE NUMERALS

| | | | |
|---|---|---|---|
| F10 | Step 1 | F11 | Step 2 |
| F12 | Step 3 | F13 | Step 4 |
| F14 | Step 5 | 1 | LED chip |
| 2 | heat sink structure | 3 | electrode |
| 4 | conducting wire | 5 | support structure |
| 6 | PCB | 61 | through-hole |
| 7 | metal material belt | 71 | spare area |
| 72 | crop area | 73 | connecting point |
| 8 | heat sink structure | | |
| | positioning hole for | | |
| | the heat sink | | |
| | structure to | | |
| | take shape | | |

F10: using a first knife mold to cut off a spare area other than those which form the heat sink structure and two opposing electrodes;

F11: using a plastic mold injection method to form a support structure on the metal material belt;

F12: using a second knife mold to cut off a crop area connecting the heat sink structure and the two opposing electrodes to let the heat sink structure and the two opposing electrodes form independent bodies;

F13: implementing wire bonding and chip bonding on the metal material belt having the basic shape and packaging the single-chip surface mounted LED structure;

F14: finally, cutting off the single-chip surface mounted LED structure from the metal material belt.

### DETAILED DESCRIPTION OF THE PREFERRED EMBODIMENT

The present invention will now be described by preferred embodiment along with accompanying drawings for better understanding of the structure, feature and performance of the LED structure disclosed in the present invention.

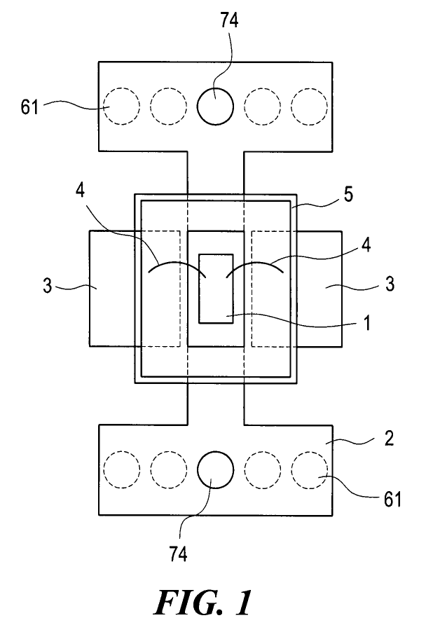

Please refer to FIG. 1 for a single-chip surface mounted LED structure disclosed in the present invention, the LED structure comprises an LED chip 1, the LED chip 1 is disposed on the heat sink structure 2, while two opposing electrodes 3 are disposed besides the heat sink structure 2, two conducting wires 4 extend from the LED chip 1 to two opposing electrodes 3, and a support structure 5 is disposed between the heat sink structure 2 and the two opposing electrodes 3 for fixing the heat sink structure 2 and the two opposing electrodes 3, and then the single-chip surface mounted LED structure 10 is packaged using traditional LED packaging method to form the packaged single-chip surface mounted LED structure.

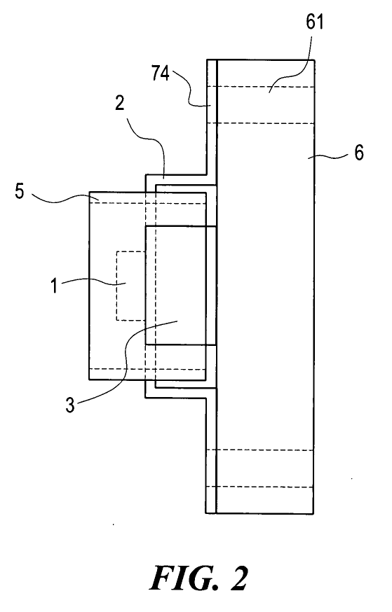

Please refer to FIG. 2. Subsequently, in practical use, the single-chip surface mounted LED structure 10 is connected via two opposing electrodes 3 to a PCB 6 using surfaced mounted (SMD) method, then it is electrically conducted to let the LED chip 1 start to emit light, the heat generated by the LED chip 1 would be dissipated via the heat sink structure 2 extended to other places, if necessary, it is viable to combine the heat sink structure 2 with the heat dissipating mechanism on the PCB 6 to dissipate the heat out of the PCB; a through-hole 61 is disposed on the PCB 6, wherein the through-hole 61 has heat conducting material such as copper powder disposed inside thereof to dissipate the heat out of the PCB 6 when the heat sink structure 2 is placed near the through-hole 61; since the heat sink structure 2 doesn't have any contact with any electrode, it would remain neutral electrically and would not interfere the operation of other circuitry.

Moreover, the heat sink structure 2 can be bent into various shapes in order to cooperate with other heat dissipating devices or to change the space arrangement to provide the best dissipating efficiency; or the heat sink structure 2 has adjustable area to achieve the best heat dissipating effect.

Please refer to FIG. 3 to FIG. 7 for the method for manufacturing the single-chip surface mounted LED structure, wherein the heat sink structure 2 and the two opposing electrodes 3 are formed on one single metal material belt 7, the method comprises the following steps:

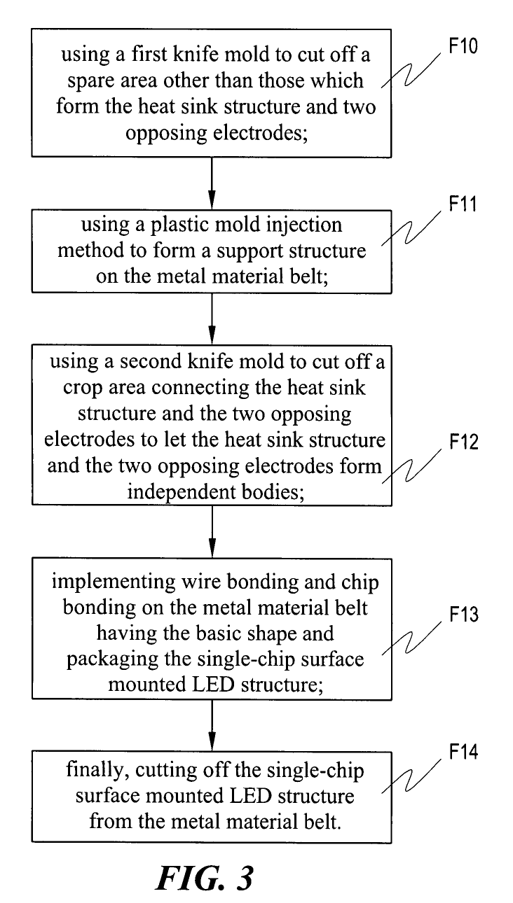

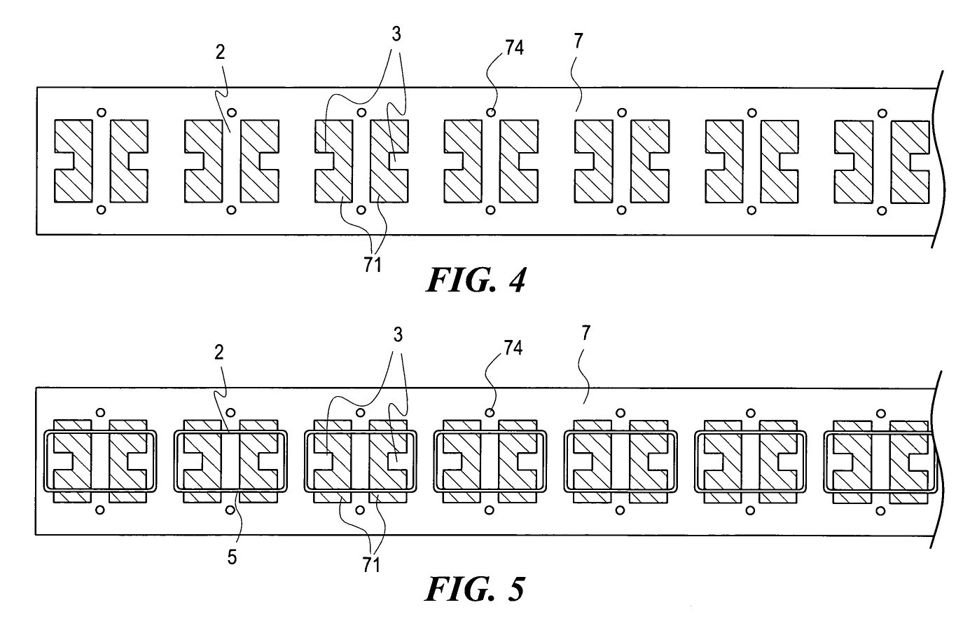

Step 1 (F10): as shown in FIG. 4, firstly using a first knife mold to cut off a spare area 71 other than those which form the heat sink structure 2 and two opposing electrodes 3 on the metal material belt 7 to form a basic shape for the heat sink structure 2 and the two opposing electrodes 3 on the metal material belt 7;

Step 2 (F11): as shown in FIG. 5, using a plastic mold injection method to form a support structure 5 on the metal material belt, wherein the support structure 5 is formed at least in the range of the heat sink structure 2 and the two opposing electrodes 3;

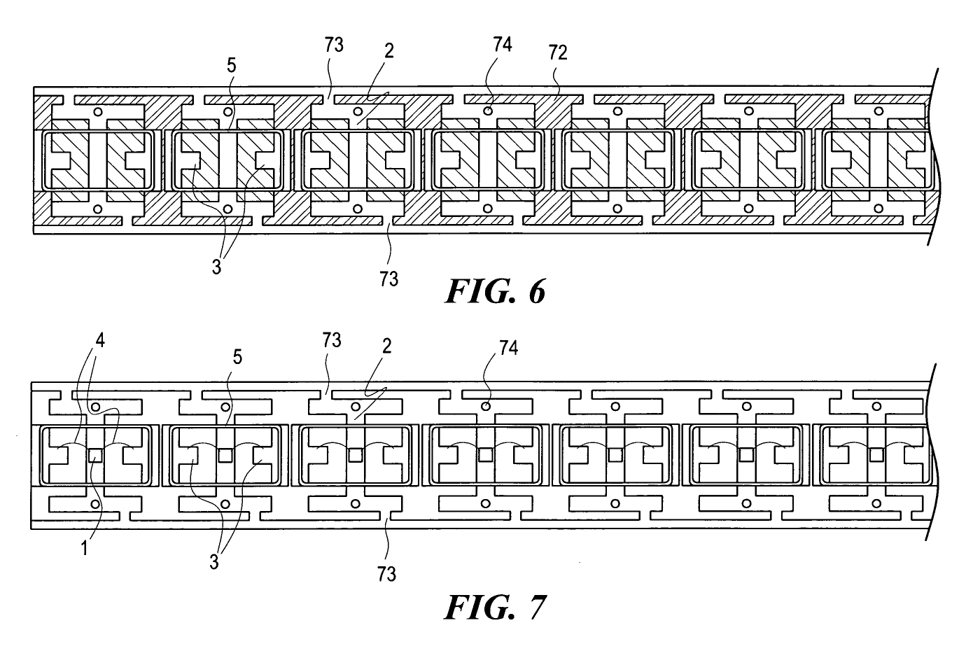

Step 3 (F12): as shown in FIG. 6, using a second knife mold to cut off a crop area connecting the heat sink structure 2 and the two opposing electrodes 3 on the metal material belt to let the heat sink structure 2 and the two opposing electrodes 3 form independent bodies yet connected and fixed in position by the support structure 5, and the heat sink structure 2 and the metal material belt 7 being connected by only a connecting point 73;

Step 4 (F13): as shown in FIG. 7, implementing wire bonding and chip bonding on the metal material belt having the basic shape, placing the LED chip 1 on the heat sink structure 2 and connecting two conducting wires 4 from the LED chip 1 to the two opposing electrodes 3 respectively, and then packaging the single-chip surface mounted LED structure;

Step 5 (F14): finally, cutting off the connecting point 73 to separate the single-chip surface mounted LED structure from the metal material belt 7, the result is shown in FIG. 2.

Many changes and modifications in the above described embodiment of the invention can, of course, be carried out without departing from the scope thereof. Accordingly, to promote the progress in science and the useful arts, the invention is disclosed and is intended to be limited only by the scope of the appended claims.

What is claimed is:

1. A method for manufacturing a single-chip surface mounted LED structure, comprises the following steps:
Step 1: using a first knife mold to cut off a spare area other than those which form a heat sink structure and two opposing electrodes on a metal material belt to form a basic shape for said heat sink structure and said two opposing electrodes on said metal material belt;
Step 2: using a plastic mold injection method to form a support structure on said metal material belt, wherein said support structure is formed at least in the range of said heat sink structure and said two opposing electrodes;
Step 3: using a second knife mold to cut off a connection area of said heat sink structure and said two opposing electrodes on said metal material belt to let said heat sink structure and said two opposing electrodes connected by said support structure, and said heat sink structure and said metal material belt being connected by only a connecting point;
Step 4: implementing wire bonding and chip bonding on said metal material belt having said basic shape and packaging said single-chip surface mounted LED structure; and
Step 5: cutting off said connecting point to separate said single-chip surface mounted LED structure from said metal material belt.

2. The method of claim 1, wherein said support structure is disposed by mold injection.

3. A single-chip surface mounted LED structure, comprises:
an LED chip as a light source;
two opposing electrodes disposed at sides of said LED chip;
two conducting wires extending from said LED chip to connect to two opposing electrodes respectively;
a heat sink structure supporting an end of said LED chip to dissipate the heat from said LED chip; and
a support structure connecting to said heat sink structure and said two opposing electrodes.

4. The single-chip surface mounted LED structure of claim 3, wherein said heat sink structure can combine other heat dissipating device to provide more efficient heat dissipating effect.

5. The single-chip surface mounted LED structure of claim 3, wherein said heat sink structure can be bent into various shapes to achieve the most heat dissipating effect.

6. The single-chip surface mounted LED structure of claim 3, wherein said heat sink structure has adjustable area to achieve the most heat dissipating effect.

7. The single-chip surface mounted LED structure of claim 3, wherein said heat sink structure and said two opposing electrodes are formed on said metal material belt at the same time.
